(19) United States
(12) Patent Application Publication
(10) Pub. No.: US 2025/0324607 A1
(43) Pub. Date: Oct. 16, 2025

(54) Ferroelectric Memory Circuitry And Method Used In Forming Ferroelectric Memory Circuitry

(71) Applicant: Micron Technology, Inc., Boise, ID (US)

(72) Inventors: Haitao Liu, Boise, ID (US); Kamal M. Karda, Boise, ID (US); Albert Fayrushin, Boise, ID (US)

(73) Assignee: Micron Technology, Inc., Boise, ID (US)

(21) Appl. No.: 19/078,790

(22) Filed: Mar. 13, 2025

Related U.S. Application Data
(60) Provisional application No. 63/632,737, filed on Apr. 11, 2024.

(51) Int. Cl. H10B 51/30; H10B 51/20

(52) U.S. Cl. CPC H10B 51/30; H10B 51/20

(57) ABSTRACT

Ferroelectric memory circuitry comprises an upper select-gate tier directly above memory-cell tiers and a lower select-gate tier directly below the memory-cell tiers. Channel-material strings extend through such. Memory cells are in individual memory-cell tiers and comprises a vertical ferroelectric transistor that comprises one of the channel-material strings, two separately-controllable control gates in one of the memory-cell tiers on laterally-opposing sides of the one channel-material string, at least a ferroelectric material in the one individual memory-cell tier laterally between one of the two control gates and the one channel-material string, and at least a gate insulator in the one individual memory-cell tier laterally between the other of the two control gates and the one channel-material string. Other embodiments, including method, are disclosed.

### TECHNICAL FIELD

Embodiments disclosed herein pertain to ferroelectric memory circuitry and to methods used in forming ferroelectric memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, sense lines, or data/sense lines) and access lines (which may also be referred to as wordlines). The digitlines may conductively interconnect memory cells along columns of the array, and the access lines may conductively interconnect memory cells along rows of the array.

Memory cells may be volatile or nonvolatile. Nonvolatile memory cells can store data for extended periods of time including when the computer is turned off. Volatile memory dissipates and therefore requires being refreshed/rewritten, in many instances multiple times per second. Regardless, memory cells are configured to retain or store memory in at least two different selectable states. In a binary system, the states are considered as either a “0” or a “1”. In other systems, at least some individual memory cells may be configured to store more than two levels or states of information.

Ferroelectric field effect transistors (FeFET) may be used as memory cells. Specifically, the FeFETs may have two selectable memory states corresponding to two different polarization modes of ferroelectric material within the FeFETS. The different polarization modes may be characterized by, for example, different threshold voltages (Vt) or by different channel conductivities for a selected operating voltage. The ferroelectric polarization mode of a FeFET may remain in the absence of power (at least for a measurable duration).

One type of ferroelectric transistor is a metal-ferroelectric-metal-insulator-semiconductor (MFMIS) transistor. Such has a gate dielectric (insulator, I) between metal (M) and semiconductor material(S). Such also has ferroelectric (F) material over the metal, and has a gate (typically comprising metal, M) over the ferroelectric material. In operation, an electric field across the ferroelectric material is used to switch the ferroelectric material from one polarization mode to another. The ferroelectric transistor comprises a pair of source/drain regions, and a channel region between the source/drain regions. Conductivity across the channel region is influenced by the polarization mode of the ferroelectric material. Another type of ferroelectric transistor is metal-ferroelectric-insulator-semiconductor (MFIS) in which ferroelectric material directly touches the insulator (i.e., in which there is no intervening metal between the ferroelectric material and the insulator).

It is desired to develop ferroelectric transistors which are scalable to ever-increasing levels of integration.

### BRIEF DESCRIPTION OF THE DRAWINGS

FIG. 1 is a diagrammatic view of a portion of memory circuitry in accordance with an embodiment of the invention.

FIG. 2 is a diagrammatic view of a portion of memory circuitry in accordance with an embodiment of the invention.

FIGS. 3-13 are diagrammatic sequential sectional and/or enlarged views of a method used in forming ferroelectric memory circuitry in accordance with some embodiments of the invention.

### DETAILED DESCRIPTION OF EXAMPLE EMBODIMENTS

Embodiments of the invention comprise ferroelectric memory circuitry and methods used in forming ferroelectric memory circuitry.

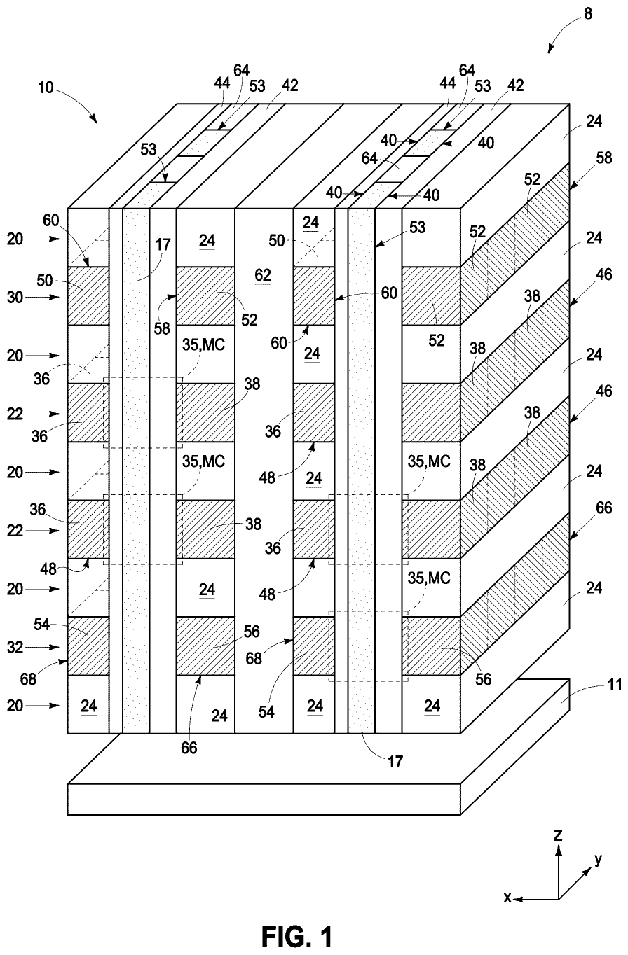

A first example structure embodiment comprising ferroelectric memory circuitry is described with reference to FIG. 1. Such depicts a construction 8 having example “x”, “y”, and “z” axes/directions. Construction 8 comprises a base substrate 11 and ferroelectric memory circuitry 10. Base substrate 11 may include any one or more of conductive/conductor/conducting, semiconductive/semiconductor/semiconducting, or insulative/insulator/insulating (i.e., electrically herein) materials. Materials may be aside, elevationally inward, or elevationally outward of the FIG. 1—depicted materials. For example, other partially or wholly fabricated components of integrated circuitry may be provided somewhere above, about, or within base substrate 11. Control and/or other peripheral circuitry for operating components within an array of ferroelectric memory circuitry 10 may also be fabricated and may or may not be wholly or partially within an array or sub-array of such memory circuitry. Further, multiple sub-arrays may also be fabricated and operated independently, in tandem, or otherwise relative one another. In this document, a “sub-array” may also be considered as an array.

Construction 8 and ferroelectric memory circuity 10 comprise vertically-alternating (in “z”) insulative tiers 20 (comprising insulative material 24; e.g., silicon dioxide) and memory-cell tiers 22 (e.g., comprising memory cells MC). Only two memory-cell tiers 22 are shown, with construction 8 likely comprising dozens, hundreds, etc. such tiers 22. An upper select-gate tier 30 (e.g., a select-gate drain tier analogous to that in 3D NAND memory circuitry) is directly above memory-cell tiers 22 and a lower select-gate tier 32 (e.g., a select-gate source tier analogous to that in 3D NAND memory circuitry) is directly below memory-cell tiers 22. Only one upper and one lower select-gate tier are shown, although more of one or the other may be included and regardless of whether multiple upper and/or multiple lower select-gate tiers are connected circuit-parallel or otherwise. Channel-material strings 53 individually extend vertically through upper select-gate tier 30, insulative and memory-cell tiers 20 and 22, and lower select-gate tier 32, and comprise channel material 17 (e.g., appropriately-doped or undoped crystalline semiconductor material, such as one or more silicon, germanium, and so-called III/V semiconductor materials [e.g., GaAs, InP, GaP, and GaN]). Only four channel-material strings 53 are shown, with an actual construction 10 likely comprising hundreds, thousands, etc. more.

Memory cells MC in individual memory-cell tiers 22 individually comprise a vertical ferroelectric transistor 35 that comprises:
one of channel-material strings 53;
two separately-controllable control gates 36 and 38 (e.g., comprising conductive metal material which may be of the same or different lateral and/or vertical thickness[es] relative one another) in one of individual memory-cell tiers 22 on laterally-opposing sides 40 (in “x”) of the one channel-material string 53;
at least a ferroelectric material 42 in the one individual memory-cell tier 22 laterally between (in “x”) one of two control gates 36, 38 (e.g., 38 as shown) and the one channel-material string 53; and at least a gate insulator 44 in the one individual memory-cell tier 22 laterally between (in “x”) the other of two control gates 36, 38 (e.g., 36 as shown and the one channel-material string 53).
   Example insulative material 62 (e.g., silicon dioxide) separates immediately-laterally-adjacent control gates 36 and 38 in immediately-laterally-adjacent transistors 35 (in “x”). Example insulative material 64 (e.g., silicon dioxide) separates immediately-laterally-adjacent channel-material strings 53 in immediately-laterally-adjacent transistors 35 (in “y”).

In one embodiment, ferroelectric material 42 is directly against conductive material of the one control gate 38 and in one embodiment gate insulator 44 is directly against conductive material of the other control gate 36. Alternately in other embodiments, such is not so directly against (not shown), for example if an intervening material that is not ferroelectric (not shown) is laterally between the ferroelectric material and the conductive material of the one control gate and/or if an intervening material that is not an insulator (not shown) is laterally between the gate insulator and the conductive material of the other control gate.

In one embodiment, the one control gate 38 comprises part of one of a plurality of conductive horizontal first access lines 46 that individually directly electrically couple together multiple of the one control gates 38 of different ones of vertical ferroelectric transistors 35 that are in different ones of memory-cell tiers 22. Further, in such one embodiment, the other control gate 36 comprises part of one of a plurality of conductive horizontal second access lines 48 that individually directly electrically couple together multiple of the other control gates 36 of different ones of vertical ferroelectric transistors 35 that are in different ones of memory-cell tiers 22.

Ferroelectric material 42 may comprise any suitable composition(s), for example one or more materials selected from the group consisting of transition metal oxide, zirconium, zirconium oxide, hafnium, hafnium oxide, lead zirconium titanate, tantalum oxide, and barium strontium titanate, and having dopant therein which comprises one or more of silicon, aluminum, lanthanum, yttrium, erbium, calcium, magnesium, strontium, and a rare earth element.

In one embodiment, ferroelectric material 42 extends vertically through upper select-gate tier 30, insulative and memory-cell tiers 20, 22, and lower select-gate tier 32. In one embodiment, gate insulator 44 extends vertically through upper select-gate tier 30, insulative and memory-cell tiers 20, 22, and lower select-gate tier 32. In one embodiment, gate insulator 44 comprises dielectric material (e.g., silicon dioxide and/or silicon nitride) and in one such embodiment is not ferroelectric. In one embodiment, ferroelectric material 42 is laterally thicker (in “x”) than gate insulator 44.

In one embodiment, upper select-gate tier 30 comprises two separately-controllable upper select gates 50 and 52 (e.g., comprising conductive metal material) therein on laterally-opposing sides 40 of the one channel-material string 53. Further, in such one embodiment, lower select-gate tier 32 comprises two separately-controllable lower select gates 54 and 56 therein on laterally-opposing sides 40 of the one channel-material string 53.

In one embodiment, one of two upper select gates 50 and 52 (e.g., 52 as shown) comprises part of one of a plurality of conductive horizontal first upper select-gate lines 58 that individually directly electrically couple together multiple of the one upper select gates 52 in upper select-gate tier 30 Further, in such one embodiment, the other of two upper select gates 50 and 52 (e.g., 50 as shown) comprises part of one of a plurality of conductive horizontal second upper select-gate lines 60 that individually directly electrically couple together multiple of the other upper select gates 50 in upper select-gate tier 30. Further, in such one embodiment, one of two lower select gates 54 and 56 (e.g., 56 as shown) comprises part of one of a plurality of conductive horizontal first lower select-gate lines 66 that individually directly electrically couple together multiple of the one lower select gates 56 in lower select-gate tier 32. Further, in such one embodiment, the other of two lower select gates 54 and 56 (e.g., 54 as shown) comprises part of one of a plurality of conductive horizontal second lower select-gate lines 68 that individually directly electrically couple together multiple of other lower select gates 54 in lower select-gate tier 32.

Embodiments as disclosed herein may be considered analogous to 3D NAND architecture and programming, yet as ferroelectric memory circuitry as known to people of skill in the art, for example as shown in K. Florent et al., “First Demonstration Of Vertically Stacked Ferroelectric Al Doped HfO₂ Devices For NAND Applications,” 2017 Symposium on VLSI Technology, Kyoto, Japan, 2017, pp. T158-T159.

Any other attribute(s) or aspect(s) as shown and/or described herein with respect to other embodiments may be used in the embodiments shown and described with reference to the above embodiments.

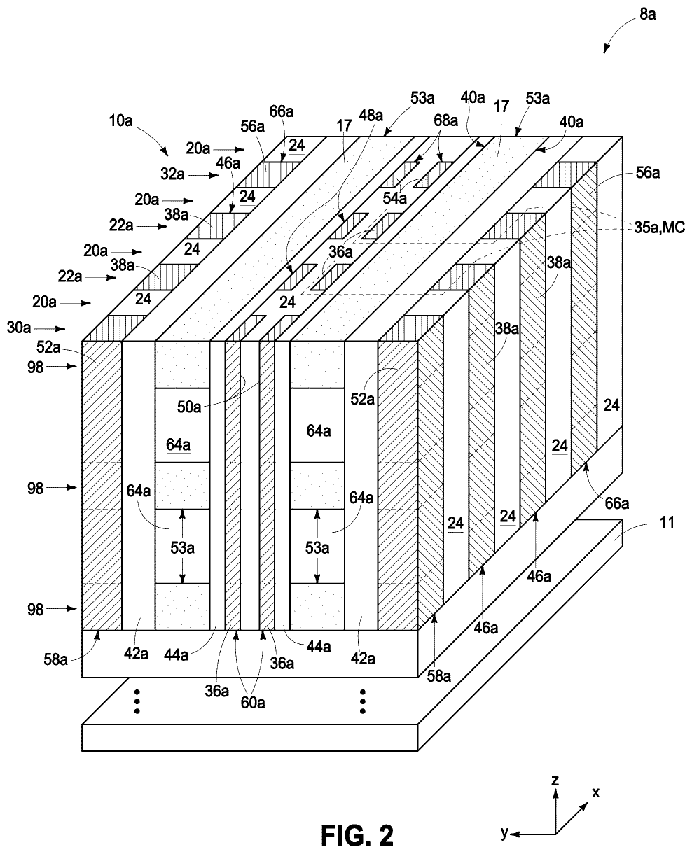

A second example structure embodiment comprising ferroelectric memory circuitry is described with reference to FIG. 2. Such depicts a construction 8a having example “x”, “y”, and “z” axes/directions. Construction 8a comprises an example base substrate 11 and ferroelectric memory circuitry 10a. Like numerals from the above-described embodiments have been used where appropriate, with some construction differences being indicated with the suffix “a” or with different numerals. Ferroelectric memory circuitry 10a comprises horizontally-alternating (in “x”) insulative rows 20a (comprising insulative material 24) and memory-cell rows 22a (comprising memory cells MC). A left-side (in “x”) select-gate row 30a is directly aside (in “x”) memory-cell rows 22a and a right-side (in “x”) select-gate row 32a is directly aside (in “x”) memory-cell rows 22a. Ferroelectric memory circuitry 10a comprises channel-material strings 53a that individually extend horizontally (in “x”) through left-side select-gate row 30a, insulative and memory-cell rows 20a and 22a, and right-side select-gate row 32a. Example construction 8a is shown as comprising three example memory-cell tiers 98 (in “z”) separated by insulative material 64a, although construction 8a may include many more memory-cell tiers 98 or only one or two memory-cell tier(s) 98 (neither of such being shown). Regardless, memory cells MC are in individual of memory-cell rows 22a and individually comprise a horizontal ferroelectric transistor 35a that comprises:
one of channel-material strings 53a;
two separately-controllable control gates 36a and 38a in one of individual memory-cell rows 22a on laterally-opposing sides 40a (in “y”) of the one channel-material string 53a;
at least a ferroelectric material 42a in the one individual memory-cell row 22a laterally between (in “y”) one of two control gates 36a, 38a (e.g., 38a as shown) and the one channel-material string; and
at least a gate insulator 44a in the one individual memory-cell row 22a laterally between (in “y”) the other of two control gates 36a, 38a (e.g., 36a as shown) and the one channel-material string 53a.
   Example insulative material 24 separates immediately-laterally-adjacent control gates 38a of different transistors 35a (in “x”).

In one embodiment, the one control gate 38a comprises part of one of a plurality of conductive vertical (in “z”) first access lines 46a that individually directly electrically couple together multiple of the one control gates 38a of different ones of horizontal ferroelectric transistors 35a that are in different ones of the memory-cell rows 22a. Further, in such one embodiment, the other control gate 36a comprises part of one of a plurality of conductive vertical (in “z”) second access lines 48a that individually directly electrically couple together multiple of the other control gates 36a of different ones of the horizontal ferroelectric transistors 35a that are in different ones of memory-cell rows 22a.

In one embodiment, ferroelectric material 42a extends horizontally through left-side select-gate row 30a, insulative and memory-cell rows 20a, 22a, and right-side select-gate row 32a. In one embodiment, gate insulator 44a extends horizontally through left-side select-gate row 30a, insulative and memory-cell rows 20a, 22a. In one embodiment, ferroelectric material 42a is laterally thicker (in “y”) than gate insulator 44a.

In one embodiment, left-side select-gate row 30a comprises two separately-controllable left-side select gates 50a and 52a therein on laterally-opposing sides 40a (in “y”) of the one channel-material string 53a. Further, in such one embodiment, right-side select-gate row 32a comprises two separately-controllable right-side select gates 54a and 56a therein on laterally-opposing sides 40a of the one channel-material string 53a.

In one embodiment, one of two left-side select gates 50a and 52a (e.g., 52a as shown) comprises part of one of a plurality of conductive vertical first left-side select-gate lines 58a that individually directly electrically couple together multiple of the one left-side select gates 52a in left-side select-gate row 30a. Further, in such one embodiment, the other of the two left-side select gates 50a and 52a (e.g., 50a as shown) comprises part of one of a plurality of conductive vertical second left-side select-gate lines 60a that individually directly electrically couple together multiple of the other left-side select gates 50a in left-side select-gate row 30a. Further, in such one embodiment, one of two right-side select gates 54a and 56a (e.g., 56a as shown) comprises part of one of a plurality of conductive vertical first right-side select-gate lines 66a that individually directly electrically couple together multiple of the one right-side select gates 56a in right-side select-gate row 32a. Further, in such one embodiment, the other of two right-side select gates 54a and 56a (e.g., 54a as shown) comprises part of one of a plurality of conductive vertical second right-side select-gate lines 68a that individually directly electrically couple together multiple of other right-side select gates 54a in right-side select-gate row 32a.

Any other attribute(s) or aspect(s) as shown and/or described herein with respect to other embodiments may be used.

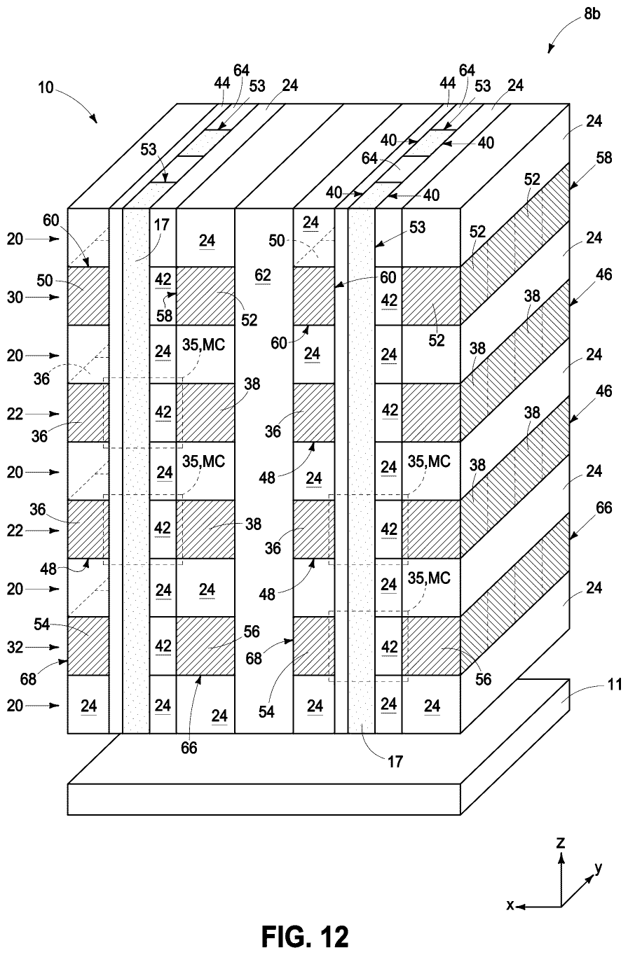

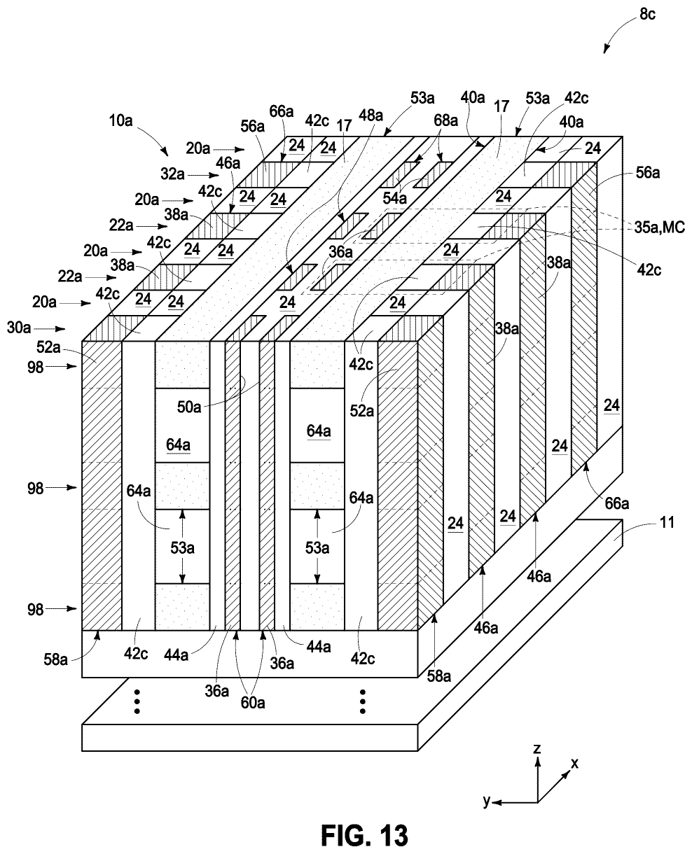

FIGS. 12 and 13 show alternate embodiment constructions 8b and 8c, respectively, that are respectively analogous to the constructions in FIGS. 1 and 2. Like numerals from the above-described embodiments have been used where appropriate, with some construction differences being indicated with the suffixes “b” and “c”, respectively, or with different numerals. In FIG. 12, ferroelectric material 42 is not vertically the continuous through vertically-alternating insulative tiers and memory-cell tiers. In FIG. 13, ferroelectric material 42c is not horizontally continuous through the left-side select-gate row, the insulative and memory-cell rows, and the right-side select-gate row. Such may also occur with respect to the gate insulator (not shown). By way of examples only, such may be so formed during fabrication by selective growth of such materials relative material that is immediately there-adjacent. Any other attribute(s) or aspect(s) as shown and/or described herein with respect to other embodiments may be used.

Prior art 3D ferroelectric transistors/memory with 3DNAND-like architecture are slow in erase and immediately-adjacent memory cells/transistors can be disturbed during program and read. Embodiments of the invention may reduce or eliminate such issues. For example, and by way of example only, gates 38/38a can be primarily used for program and erase and gates 36/36a can be primarily used for read, due to 38/38a and 36/36a being separated and separately controllable relative one another. Such may result in little if any program/read disturb and a large string current through the channel. For example, and by way of example only, to write a “0” to a transistor 35/35a, its gate 38/38a can be biased at a suitable negative voltage, its gate 36/36a biased at OV or suitable positive voltage (programming voltage, V_{pgm}), and with select gates 50/50a, 52/52a, 54/54a, and 56/56a held at 0V. To program a “1” or read transistor 35/35a, its gate 38/38a can be biased at a suitable positive voltage, its gate 36/36a biased at a suitable negative voltage, select gates 52/52a and 56/56a are held at 0V, and select gates 50/50a and 54/54a biased at one-half the programming voltage (Vₚₐₛₛ).

Embodiments of the invention encompass methods used in forming ferroelectric memory circuitry, by way of example only that incorporates device/structure as referred to above. Nevertheless, the method embodiments may incorporate, form, and/or have any of the attributes described with respect to device embodiments.

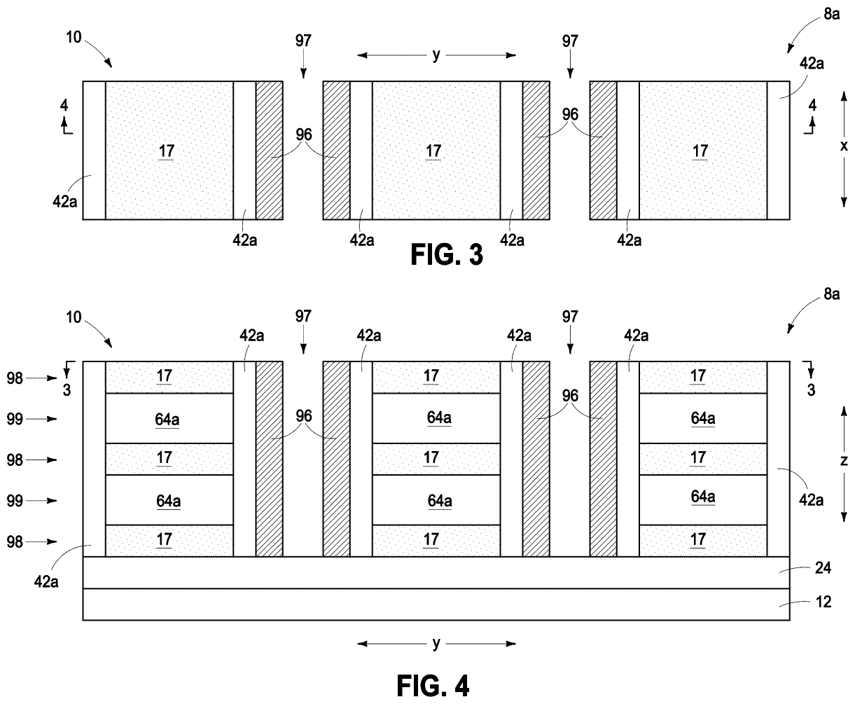

FIGS. 3-11, by way of example, sequentially show predecessor constructions 8a in an example method used in forming ferroelectric memory circuitry, with such circuitry comprising memory cells that individually comprise a horizontal ferroelectric transistor.

Referring to FIGS. 3 and 4, vertically-alternating (in “z”) insulative tiers 99 and channel-material tiers 98 have been formed above a substrate comprising insulative material 24 directly above semiconductor material 12 (e.g., undoped monocrystalline silicon). First trenches 97 have been formed to extend through tiers 98 and 99 and extend horizontally along a first direction “x”. First trenches 97 comprise ferroelectric material 42a that is laterally outward of conductive material 96 in a second direction “y” that is orthogonal to first direction x.

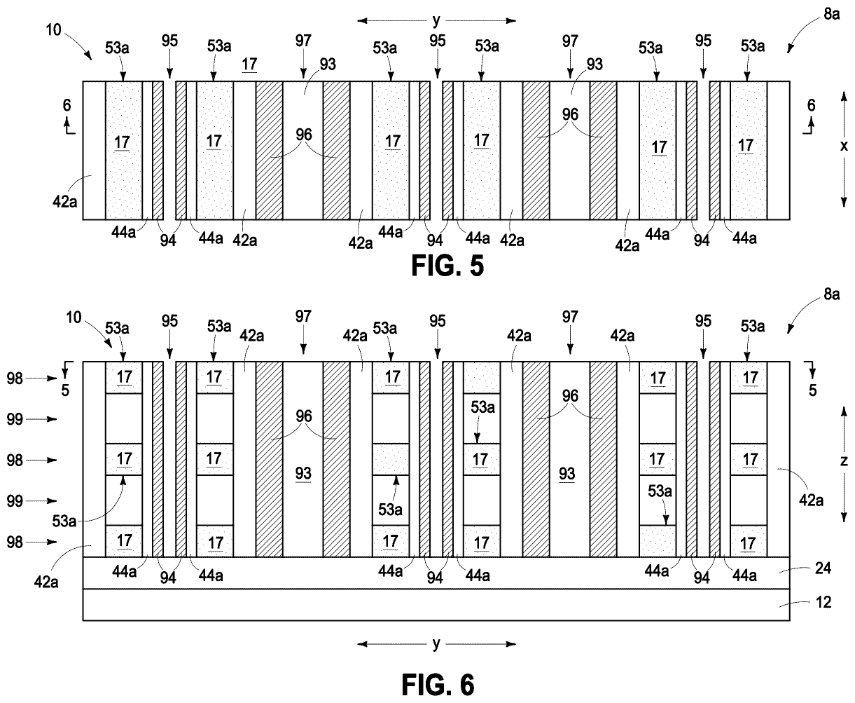

Referring to FIGS. 5 and 6, second trenches 95 have been formed through insulative tiers 99 and channel-material tiers 98 (thereby forming channel-material strings 53a ). Second trenches 95 extend horizontally along first direction “x” laterally between and parallel first trenches 97. Second trenches 95 comprise gate-insulator material 44a that is laterally outward of conducting material 94 in second direction “y”. A sacrificial material 93 (e.g., silicon dioxide, carbon, silicon nitride, etc.) may be formed in remaining volume of first trenches 97 prior to forming materials 44 and 94.

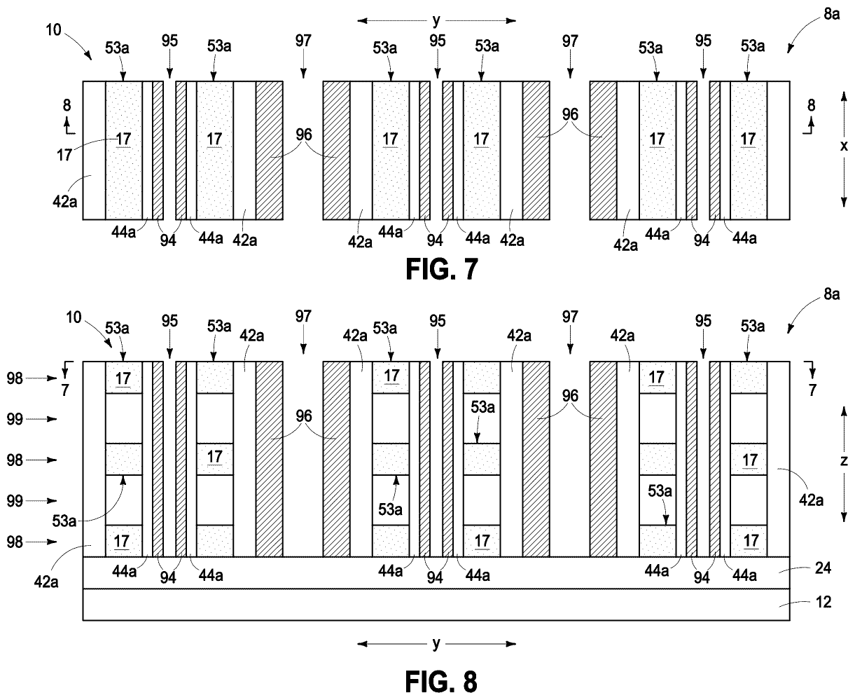

Referring to FIGS. 7 and 8, sacrificial material 93 (when present and not shown) has been removed (e.g., by etching) selectively relative to exposed other materials during such removing.

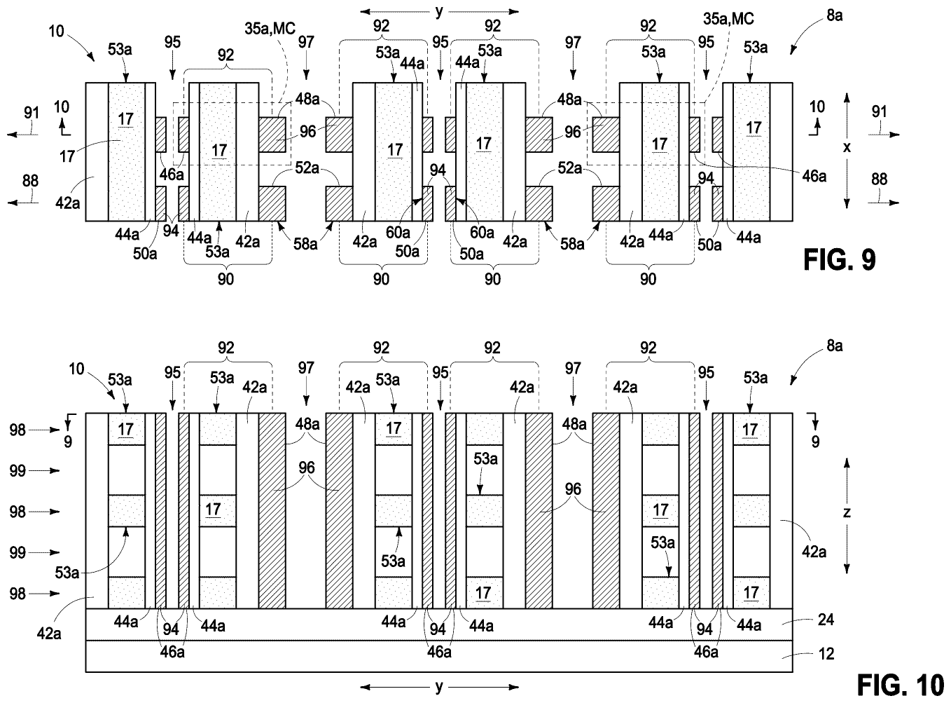

Referring to FIGS. 9 and 10, conductive and conducting materials 96 and 94, respectively, have been patterned to form pairs 92 of two separately-controllable access lines 46a and 48a. Such pairs 92 are horizontally spaced from one another in first direction “x” (see FIG. 2 where multiple such pairs are shown, although not there numerically so designated). Individual access lines 46a and 48a in individual pairs 92 are linearly-aligned in second direction “y” relative one another (e.g., along lines 91; only one line 91 being shown). In one embodiment and as shown, conductive and conducting materials 96 and 94, respectively, have also been patterned to form pairs 90 (see FIG. 2 where multiple such pairs [e.g., left and right pairs in “x”] are shown, although not there numerically so designated) of two separately-controllable select-gate lines (e.g., in FIG. 2, left select-gate lines 58a and 60a and in FIG. 2. right select-gate lines 66a and 66a). Such pairs 90 are horizontally spaced from one another in first direction “x”. Individual of the select-gate lines in individual pairs 90 are linearly-aligned in second direction “y” relative one another (e.g., along lines 88; only one line 88 being shown as only one pair 90 is shown in FIG. 9). Memory cells MC have been formed that individually comprise a ferroelectric transistor 35a that comprises:
one of channel-material strings tiers 53a;
two separately-controllable control gates 36a and 38a that comprise part of one of pairs 92 of two separately-controllable access lines 46a and 48a;
the ferroelectric material 42a ; and
gate-insulator material 44a.

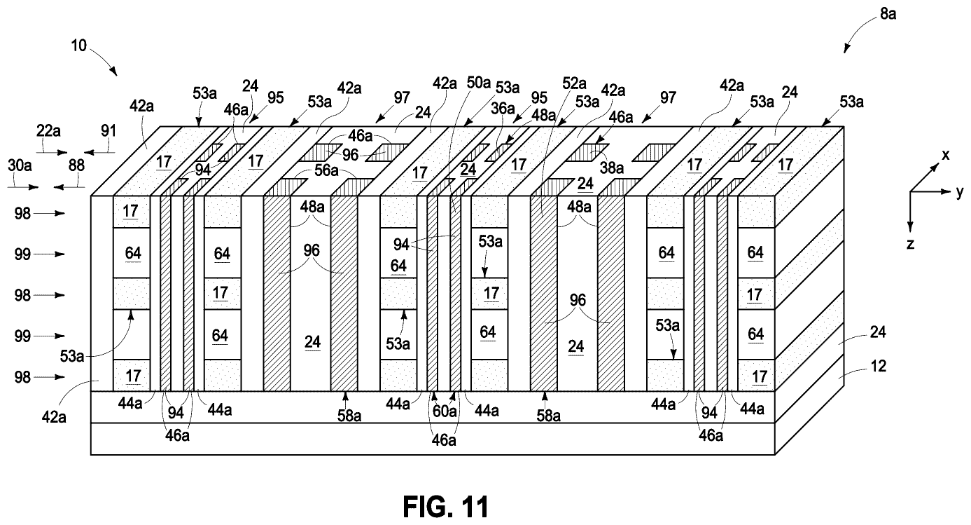

Referring to FIG. 11, and in one embodiment, remaining volume of first trenches 97 and second trenches 95 have been filled with solid insulative material 24.

Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction (“z” direction). “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components). Analogously, “directly aside” requires at least some vertical overlap of two stated regions/materials/components relative one another.

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, ferroelectric memory circuitry comprises vertically-alternating insulative tiers and memory-cell tiers. An upper select-gate tier is directly above the memory-cell tiers and a lower select-gate tier is directly below the memory-cell tiers. Channel-material strings individually extend vertically through the upper select-gate tier, the insulative and memory-cell tiers, and the lower select-gate tier. Memory cells are in individual of the memory-cell tiers. The memory cells individually comprise a vertical ferroelectric transistor that comprises one of the channel-material strings. Two separately-controllable control gates are in one of the individual memory-cell tiers on laterally-opposing sides of the one channel-material string. At least a ferroelectric material is in the one individual memory-cell tier laterally between one of the two control gates and the one channel-material string. At least a gate insulator is in the one individual memory-cell tier laterally between the other of the two control gates and the one channel-material string.

In some embodiments, ferroelectric memory circuitry comprises horizontally-alternating insulative rows and memory-cell rows. A left-side select-gate row is directly aside the memory-cell rows and a right-side select-gate row is directly aside the memory-cell rows. Channel-material strings individually extend horizontally through the left-side select-gate row, the insulative and memory-cell rows, and the right-side select-gate row. Memory cells are in individual of the memory-cell rows. The memory cells individually comprise a horizontal ferroelectric transistor that comprises one of the channel-material strings. Two separately-controllable control gates are in one of the individual memory-cell rows on laterally-opposing sides of the one channel-material string. At least a ferroelectric material is in the one individual memory-cell row laterally between one of the two control gates and the one channel-material string. At least a gate insulator is in the one individual memory-cell row laterally between the other of the two control gates and the one channel-material string.

In some embodiments, a method used in forming ferroelectric memory circuitry comprises forming vertically-alternating insulative tiers and channel-material tiers having first trenches extending there-through. The first trenches extend horizontally along a first direction and comprise ferroelectric material that is laterally outward of conductive material in a second direction that is orthogonal to the first direction. Second trenches are formed through the insulative tiers and the channel-material tiers. The second trenches extend horizontally along the first direction laterally between and parallel the first trenches. The second trenches comprise gate-insulator material that is laterally outward of conducting material in the second direction. The forming of the second trenches forms channel-material strings in individual of the channel-material tiers. The conductive and conducting materials are patterned to form pairs of two separately-controllable access lines. The pairs of two separately-controllable access lines are horizontally spaced from one another in the first direction. Individual of the two separately-controllable access lines in individual of the pairs of two separately-controllable access lines are linearly-aligned in the second direction relative one another. Memory cells are formed that individually comprise a ferroelectric transistor. The ferroelectric transistor comprises one of the channel-material strings, two separately-controllable control gates that comprise part of one of the pairs of the two separately-controllable access lines, the ferroelectric material; and the gate-insulator material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. Ferroelectric memory circuitry comprising:
vertically-alternating insulative tiers and memory-cell tiers;
an upper select-gate tier directly above the memory-cell tiers and a lower select-gate tier directly below the memory-cell tiers;
channel-material strings that individually extend vertically through the upper select-gate tier, the insulative and memory-cell tiers, and the lower select-gate tier; and
memory cells in individual of the memory-cell tiers, the memory cells individually comprising a vertical ferroelectric transistor that comprises:
one of the channel-material strings;
two separately-controllable control gates in one of the individual memory-cell tiers on laterally-opposing sides of the one channel-material string;
at least a ferroelectric material in the one individual memory-cell tier laterally between one of the two control gates and the one channel-material string; and
at least a gate insulator in the one individual memory-cell tier laterally between the other of the two control gates and the one channel-material string.

2. The ferroelectric memory circuitry of claim 1 wherein the ferroelectric material is directly against conductive material of the one control gate.

3. The ferroelectric memory circuitry of claim 1 wherein the gate insulator is directly against conductive material of the other control gate.

4. The ferroelectric memory circuitry of claim 1 wherein,
the upper select-gate tier comprises two separately-controllable upper select gates therein on the laterally-opposing sides of the one channel-material string; and
the lower select-gate tier comprises two separately-controllable lower select gates therein on the laterally-opposing sides of the one channel-material string.

5. The ferroelectric memory circuitry of claim 4 wherein
one of the two upper select gates comprises part of one of a plurality of conductive horizontal first upper select-gate lines that individually directly electrically couple together multiple of the one upper select gates in the upper select-gate tier;
the other of the two upper select gates comprises part of one of a plurality of conductive horizontal second upper select-gate lines that individually directly electrically couple together multiple of the other upper select gates in the upper select-gate tier;
one of the two lower select gates comprises part of one of a plurality of conductive horizontal first lower select-gate lines that individually directly electrically couple together multiple of the one lower select gates in the lower select-gate tier; and
the other of the two lower select gates comprises part of one of a plurality of conductive horizontal second lower select-gate lines that individually directly electrically couple together multiple of the other lower select gates in the lower select-gate tier.

6. The ferroelectric memory circuitry of claim 1 wherein.
the one control gate comprises part of one of a plurality of conductive horizontal first access lines that individually directly electrically couple together multiple of the one control gates of different ones of the vertical ferroelectric transistors that are in different ones of the memory-cell tiers; and
the other control gate comprises part of one of a plurality of conductive horizontal second access lines that individually directly electrically couple together multiple of the other control gates of different ones of the vertical ferroelectric transistors that are in different ones of the memory-cell tiers.

7. The ferroelectric memory circuitry of claim 6 wherein,
the upper select-gate tier comprises two separately-controllable upper select gates therein on the laterally-opposing sides of the one channel-material string; and
the lower select-gate tier comprises two separately-controllable lower select gates therein on the laterally-opposing sides of the one channel-material string.

8. The ferroelectric memory circuitry of claim 7 wherein
one of the two upper select gates comprises part of one of a plurality of conductive horizontal first upper select-gate lines that individually directly electrically couple together multiple of the one upper select gates in the upper select-gate tier;
the other of the two upper select gates comprises part of one of a plurality of conductive horizontal second upper select-gate lines that individually directly electrically couple together multiple of the other upper select gates in the upper select-gate tier;
one of the two lower select gates comprises part of one of a plurality of conductive horizontal first lower select-gate lines that individually directly electrically couple together multiple of the one lower select gates in the lower select-gate tier; and
the other of the two lower select gates comprises part of one of a plurality of conductive horizontal second lower select-gate lines that individually directly electrically couple together multiple of the other lower select gates in the lower select-gate tier.

9. The ferroelectric memory circuitry of claim 1 wherein the gate insulator comprises dielectric material.

10. The ferroelectric memory circuitry of claim 9 wherein the gate insulator is not ferroelectric.

11. The ferroelectric memory circuitry of claim 1 wherein the ferroelectric material is laterally thicker than the gate insulator.

12. The ferroelectric memory circuitry of claim 1 wherein the ferroelectric material extends vertically through the upper select-gate tier, the insulative and memory-cell tiers, and the lower select-gate tier.

13. The ferroelectric memory circuitry of claim 1 wherein the ferroelectric material is not vertically continuous through the vertically-alternating insulative tiers and memory-cell tiers.

14. The ferroelectric memory circuitry of claim 1 wherein the gate insulator extends vertically through the upper select-gate tier, the insulative and memory-cell tiers, and the lower select-gate tier.

15. Ferroelectric memory circuitry comprising:
horizontally-alternating insulative rows and memory-cell rows;
a left-side select-gate row directly aside the memory-cell rows and a right-side select-gate row directly aside the memory-cell rows;
channel-material strings that individually extend horizontally through the left-side select-gate row, the insulative and memory-cell rows, and the right-side select-gate row; and
memory cells in individual of the memory-cell rows, the memory cells individually comprising a horizontal ferroelectric transistor that comprises:
one of the channel-material strings;
two separately-controllable control gates in one of the individual memory-cell rows on laterally-opposing sides of the one channel-material string;
at least a ferroelectric material in the one individual memory-cell row laterally between one of the two control gates and the one channel-material string; and
at least a gate insulator in the one individual memory-cell row laterally between the other of the two control gates and the one channel-material string.

16. The ferroelectric memory circuitry of claim 15 wherein,
the left-side select-gate row comprises two separately-controllable left-side select gates therein on the laterally-opposing sides of the one channel-material string; and
the right-side select-gate row comprises two separately-controllable right-side select gates therein on the laterally-opposing sides of the one channel-material string.

17. The ferroelectric memory circuitry of claim 16 wherein,
one of the two left-side select gates comprises part of one of a plurality of conductive vertical first left-side select-gate lines that individually directly electrically couple together multiple of the one left-side select gates in the left-side select-gate row;
the other of the two left-side select gates comprises part of one of a plurality of conductive vertical second left-side select-gate lines that individually directly electrically couple together multiple of the other left-side select gates in the left-side select-gate row;
one of the two right-side select gates comprises part of one of a plurality of conductive vertical first right-side select-gate lines that individually directly electrically couple together multiple of the one right-side select gates in the right-side select-gate row; and
the other of the two right-side select gates comprises part of one of a plurality of conductive vertical second right-side select-gate lines that individually directly electrically couple together multiple of the other right-side select gates in the right-side select-gate row.

18. The ferroelectric memory circuitry of claim 15 wherein,
the one control gate comprises part of one of a plurality of conductive vertical first access lines that individually directly electrically couple together multiple of the one control gates of different ones of the horizontal ferroelectric transistors that are in different ones of the memory-cell rows; and
the other control gate comprises part of one of a plurality of conductive vertical second access lines that individually directly electrically couple together multiple of the other control gates of different ones of the horizontal ferroelectric transistors that are in different ones of the memory-cell rows.

19. The ferroelectric memory circuitry of claim 18 wherein,
the left-side select-gate row comprises two separately-controllable left-side select gates therein on the laterally-opposing sides of the one channel-material string; and
the right-side select-gate row comprises two separately-controllable right-side select gates therein on the laterally-opposing sides of the one channel-material string.

20. The ferroelectric memory circuitry of claim 19 wherein,
one of the two left-side select gates comprises part of one of a plurality of conductive vertical first left-side select-gate lines that individually directly electrically couple together multiple of the one left-side select gates in the left-side select-gate row;
the other of the two left-side select gates comprises part of one of a plurality of conductive vertical second left-side select-gate lines that individually directly electrically couple together multiple of the other left-side select gates in the left-side select-gate row;
one of the two right-side select gates comprises part of one of a plurality of conductive vertical first right-side select-gate lines that individually directly electrically couple together multiple of the one right-side select gates in the right-side select-gate row; and
the other of the two right-side select gates comprises part of one of a plurality of conductive vertical second right-side select-gate lines that individually directly electrically couple together multiple of the other right-side select gates in the right-side select-gate row.

21. The ferroelectric memory circuitry of claim 15 wherein the ferroelectric material extends horizontally through the left-side select-gate row, the insulative and memory-cell rows, and the right-side select-gate row.

22. The ferroelectric memory circuitry of claim 15 wherein the ferroelectric material is not horizontally continuous through the left-side select-gate row, the insulative and memory-cell rows, and the right-side select-gate row.

23. A method used in forming ferroelectric memory circuitry, comprising:
forming vertically-alternating insulative tiers and channel-material tiers having first trenches extending there-through, the first trenches extending horizontally along a first direction and comprising ferroelectric material that is laterally outward of conductive material in a second direction that is orthogonal to the first direction;
forming second trenches through the insulative tiers and the channel-material tiers, the second trenches extending horizontally along the first direction laterally between and parallel the first trenches, the second trenches comprising gate-insulator material that is laterally outward of conducting material in the second direction, the forming of the second trenches forming channel-material strings in individual of the channel-material tiers;
patterning the conductive and conducting materials to form pairs of two separately-controllable access lines, the pairs of two separately-controllable access lines being horizontally spaced from one another in the first direction, individual of the two separately-controllable access lines in individual of the pairs of two separately-controllable access lines being linearly-aligned in the second direction relative one another; and
forming memory cells that individually comprise a ferroelectric transistor that comprises:
one of the channel-material strings;
two separately-controllable control gates that comprise part of one of the pairs of the two separately-controllable access lines;
the ferroelectric material; and
the gate-insulator material.

24. The method of claim 23 wherein the patterning of the conductive and conducting materials forms pairs of two separately-controllable select-gate lines, the pairs of two separately-controllable select-gate lines being horizontally spaced from one another in the first direction, individual of the two separately-controllable select-gate lines in individual of the pairs of two separately-controllable select-gate lines being linearly-aligned in the second direction relative one another.

25. The method of claim 23 comprising after the patterning, filling remaining volume of the first and second trenches with solid insulating material.

26. The method of claim 23 comprising:
filling remaining volume of the first trenches with sacrificial material prior to forming the second trenches; and
removing the sacrificial material after forming the second trenches and prior to the patterning.

27. The method of claim 23 comprising forming the gate-insulator material to comprise dielectric material.

28. The method of claim 27 wherein the gate insulator in not ferroelectric.

29. The method of claim 23 wherein the ferroelectric material is laterally thicker than the gate-insulator material.

30. The method of claim 23 wherein the patterning is conducted selectively relative to the ferroelectric material and the gate-insulator material, the ferroelectric material and the gate-insulator material extending all along channel material of the channel-material strings in a finished-circuitry construction.
